(19) United States
(12) Patent Application Publication
(10) Pub. No.: US 2024/0282838 A1
(43) Pub. Date: Aug. 22, 2024

(54) DEVICE HAVING HYBRID NANOSHEET STRUCTURE AND METHOD

(71) Applicant: Taiwan Semiconductor Manufacturing Co., Ltd., Hsinchu (TW)

(72) Inventors: Jung-Hung CHANG, Hsinchu (TW); Tsung-Han CHUANG, Hsinchu (TW); Fu-Cheng CHANG, Hsinchu (TW); Shih-Cheng CHEN, Hsinchu (TW); Chia-Cheng TSAI, Hsinchu (TW); Kuo-Cheng CHIANG, Hsinchu (TW)

(21) Appl. No.: 18/343,680

(22) Filed: Jun. 28, 2023

Related U.S. Application Data
(60) Provisional application No. 63/485,393, filed on Feb. 16, 2023.

(51) Int. Cl. H01L 29/423; H01L 21/8238; H01L 27/092; H01L 29/06; H01L 29/08; H01L 29/66; H01L 29/775; H01L 29/786

(52) U.S. Cl. CPC H01L 29/42392; H01L 21/823814; H01L 21/823864; H01L 27/092; H01L 29/0649; H01L 29/0673; H01L 29/0847; H01L 29/66439; H01L 29/66545; H01L 29/6656; H01L 29/775; H01L 29/78696; H01L 21/823807

(57) ABSTRACT

A device includes: a stack of nanostructures; a gate structure that wraps around the nanostructures; an isolation region between the stack of nanostructures and another stack of nanostructures adjacent thereto along a first direction; a source/drain region that abuts at least one of the nanostructures; and a spacer layer that is on sidewalls of the gate structure and on sidewalls of the source/drain region, the spacer layer covering an area between the source/drain region and a neighboring source/drain region of another transistor along the first direction.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1C are diagrammatic cross-sectional side views of a portion of an IC device in accordance with embodiments of the present disclosure.

FIGS. 2A-13F are views of various embodiments of an IC device at various stages of fabrication according to various aspects of the present disclosure.

FIG. 14 is a flowchart illustrating a method of fabricating a semiconductor device according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to electronic devices, and more particularly to electronic devices that include field-effect transistors (FETs), such as planar FETs, three-dimensional fin FETs (FinFETs) or nanostructure FETs, such as gate-all-around (GAA) FETs, nanosheet (NS) FETs, nanowire (NW) FETs, and the like. In advanced technology nodes, a GAA hybrid circuit cell may include different active area widths for offering different effective widths (Weff). For example, different Weff is beneficial for both speed performance and power efficiency, wherein a logic cell with small Weff may have improved power efficiency and a logic cell with large Weff may have improved speed performance. Forming different active area widths is a straightforward approach to provide different Weff. However, large active area width increases cell area, and small active area width may increase difficulty forming inner spacers and cause source/drain epitaxial growth process window constraints. Multiple sheet number (or “hybrid sheet”) structures provide different Weff for logic circuit cells while improving cell size and process window. However, different channel epitaxy and active area etch may increase difficulty in active area patterning and nanosheet etching.

In embodiments of the disclosure, multiple sheets are provided for hybrid logic circuit cells by growing epitaxial layers from the bottom of a source/drain opening up to isolate sheets from the later-formed source/drain regions. Devices (e.g., GAAFETs) having fewer sheets in contact with the source/drain regions due to taller epitaxial layers benefit in power savings, and devices having more sheets in contact with the source/drain regions due to shorter epitaxial layers benefit in higher speed. A bottom insulator layer or “Flexible Bottom Insulator” (FBI) at different bottom-up epitaxial layer heights is beneficial to reduce mesa leakage current.

In a process that forms the source/drain openings in which multiple channel disabling epitaxial layers are deposited to disable one or more nanosheets (e.g., by isolating them from the source/drain regions), multiple etch operations increases risk of shallow trench isolation (STI) breakthrough exposing semiconductor fin sidewalls. Epitaxial growth of source/drain regions may then cause unwanted growth from the exposed sidewalls of the semiconductor fin(s). In severe cases, the unwanted growth may establish an electrical current path or “bridging” between neighboring semiconductor fins.

In embodiments of the disclosure, the STI is protected by a spacer layer that is not removed from over the STI prior to formation of the source/drain openings and subsequent etch operations during formation of the channel disabling layers. As such, little to no extra STI loss is incurred, which reduces risk of polysilicon collapse when using a stepping undoped silicon epitaxial process. Protection of the STI may be by a mask, such as a bottom-layer antireflective coating or “BARC.”

Nanostructure device structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the nanostructure device structure.

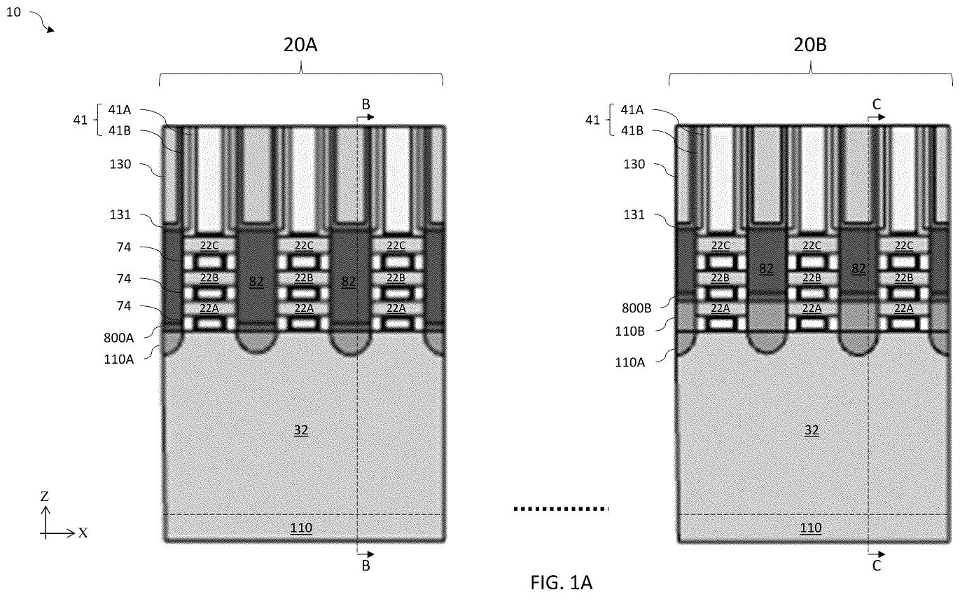

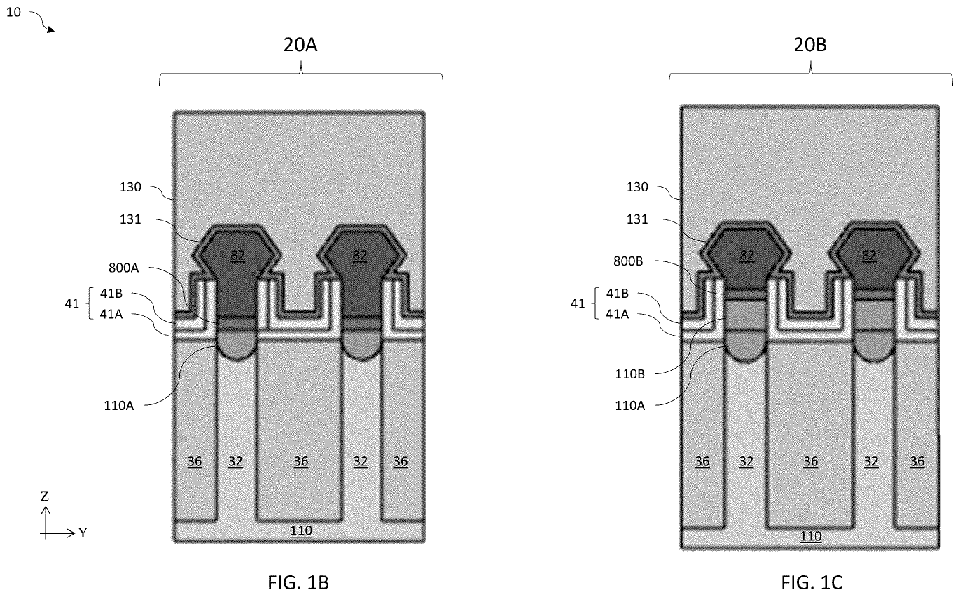

FIGS. 1A-1C are diagrammatic cross-sectional side views of a portion of an IC chip 10 in accordance with various embodiments. FIG. 1A depicts a portion of the IC chip 10 cut along a semiconductor fin 32 (or “fin” or “fin structure”) along a first direction, which is an X-axis direction. FIGS. 1B and 1C depict portions of the IC chip 10 cut along source/drain regions 82 along a second direction, which is a Y-axis direction perpendicular to the X-axis direction.

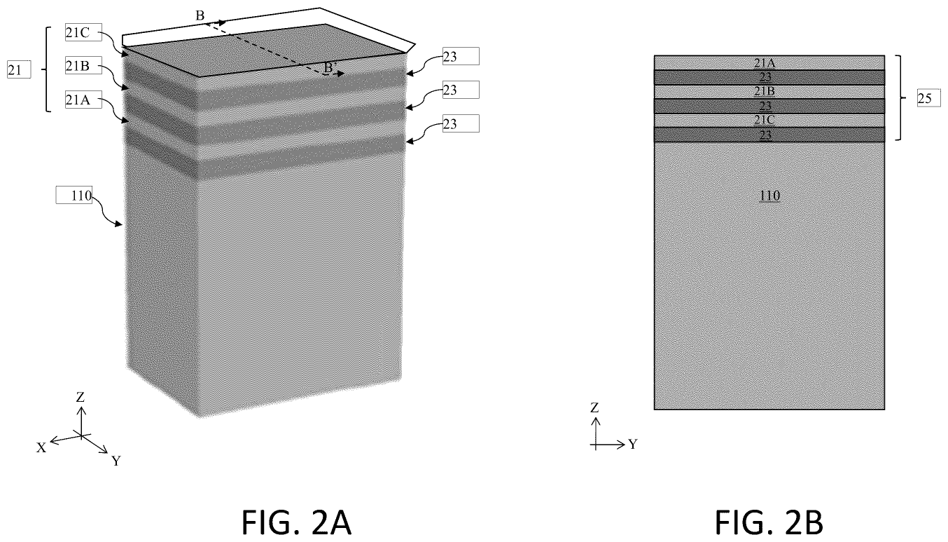

In FIG. 1A, a portion of the IC chip 10 is shown. The IC chip 10 includes a first nanostructure device region 20A and a second nanostructure device region 20B. In the first nanostructure device region 20A, all channels 22A, 22B, 22C of each device are in contact with a source/drain region 82 on either side thereof. In the second nanostructure device region 20B, lowermost channels 22A of each device are isolated from source/drain regions 82 and other channels 22B, 22C are in contact with the source/drain regions 82. The lowermost channels 22A in the second nanostructure device region 20B are in contact with epitaxial layers 110B and optionally bottom dielectric layers 800B. Other features of the IC chip 10 are described in greater detail below with reference to process 1000 as depicted in FIGS. 2A-14.

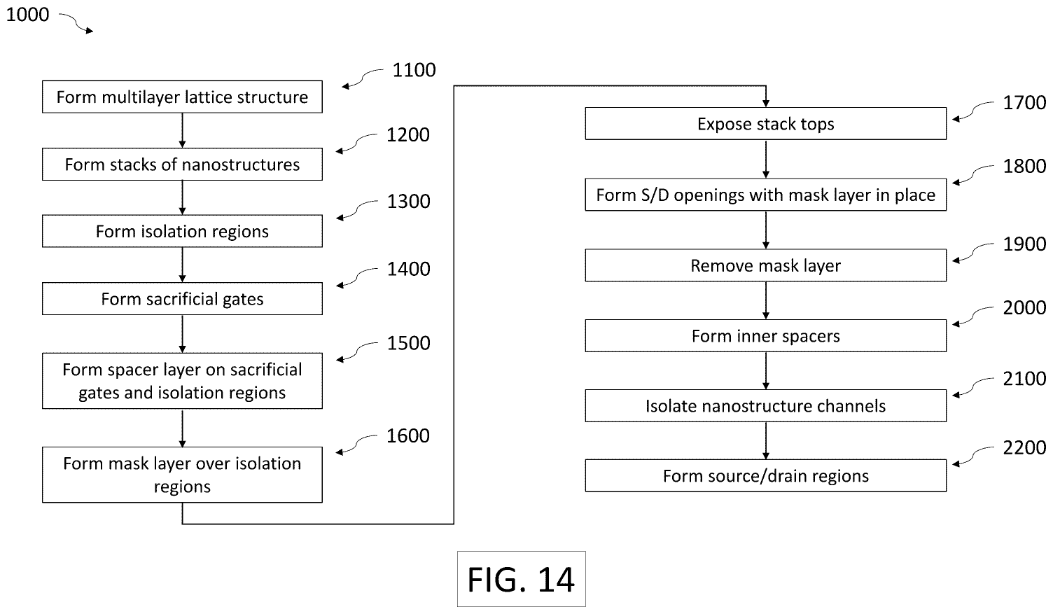

FIGS. 2A-13F are views of various embodiments of an IC device, e.g., the IC chip 10, at various stages of fabrication according to various aspects of the present disclosure. FIG. 14 is a flowchart illustrating a method 1000 of fabricating a semiconductor device according to various aspects of the present disclosure. The various stages of fabrication of the IC device illustrated in FIGS. 2A-13F may be performed in accordance with the method of FIG. 14. FIG. 14 illustrates a flowchart of method 1000 for forming an IC device or a portion thereof from a workpiece, according to one or more aspects of the present disclosure. Method 1000 is an example and is not intended to limit the present disclosure to what is explicitly illustrated in method 1000. Additional acts can be provided before, during and after the method 1000 and some acts described can be replaced, eliminated, or moved around for additional embodiments of the methods. Not all acts are described herein in detail for reasons of simplicity. Method 1000 is described below in conjunction with fragmentary perspective and/or cross-sectional views of a workpiece, shown in FIGS. 2A-13F, at different stages of fabrication according to embodiments of method 1000. For avoidance of doubt, throughout the figures, the X direction is perpendicular to the Y direction and the Z direction is perpendicular to both the X direction and the Y direction. It is noted that, because the workpiece may be fabricated into a semiconductor device, the workpiece may be referred to as the semiconductor device as is beneficial to the context.

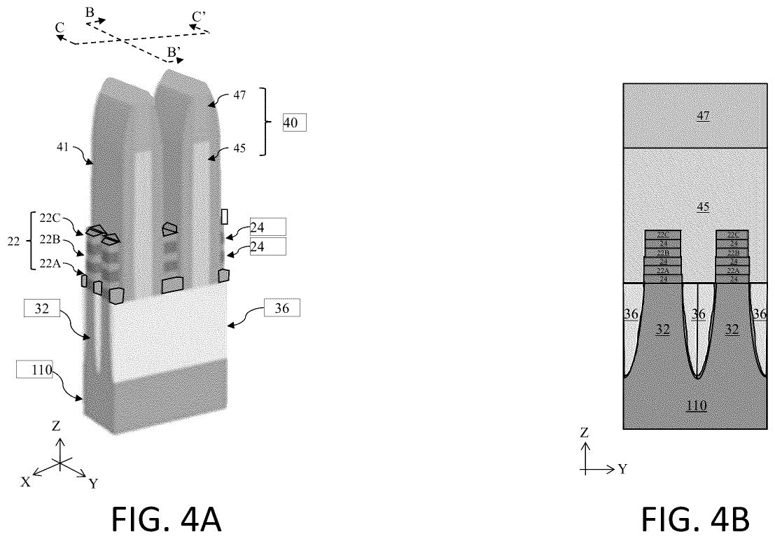

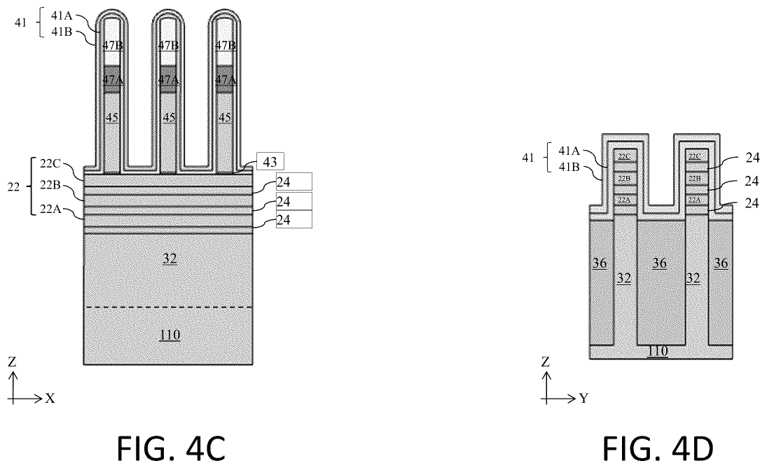

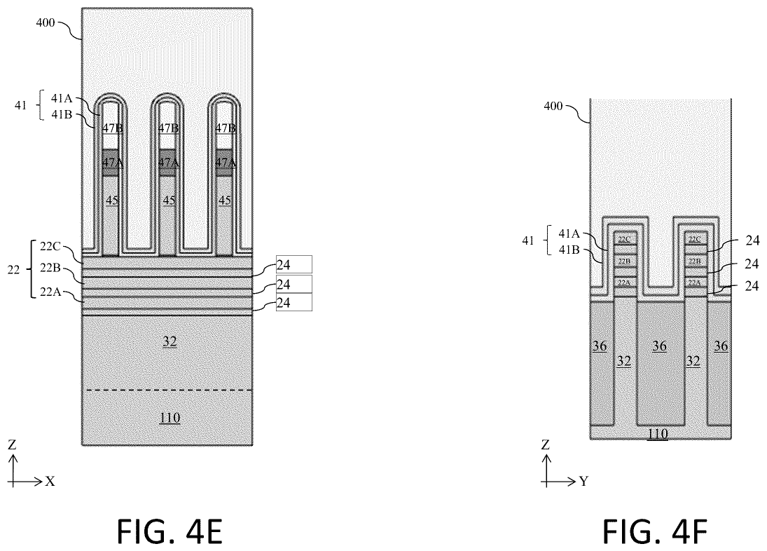

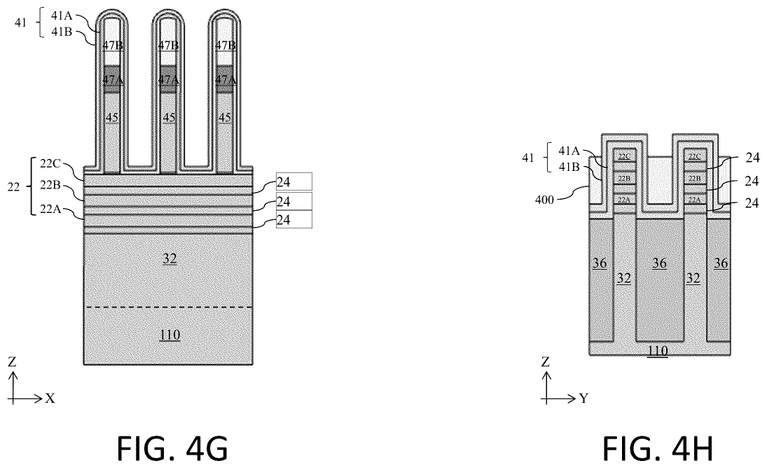

FIGS. 2A through 13F are diagrammatic perspective and cross-sectional views of intermediate stages in the manufacturing of FETs, such as nanosheet FETs, in accordance with some embodiments. FIGS. 2A, 3A, 4A, 5A, 6A, 7A, 8A, 9A and 10A illustrate perspective views. FIGS. 2B, 3B, 4B, 4D, 4F, 4H, 5B, 5D, 6B, 7B, 7E, 7G, 7I, 7K, 7L, 7N, 70, 8B, 8E, 8F, 8G, 9B, 10B, 11D, 12, 13B, 13D, 13F illustrate side views taken along reference cross-section B-B′ (gate cut or source/drain cut; YZ plane) shown in FIGS. 2A, 3A, 4A. FIGS. 4C, 4E, 4G, 5C, 6C, 7C, 7D, 7F, 7H, 7J, 7M, 8C, 8D, 9C, 10C, 11A, 11B, 11C, 13A, 13C, 13E illustrate side views taken along reference cross-section C-C′ (fin cut; XZ plane) illustrated in FIG. 4A.

In FIG. 2A and FIG. 2B, a substrate 110 is provided. The substrate 110 may be a semiconductor substrate, such as a bulk semiconductor, or the like, which may be doped (e.g., with a p-type or an n-type dopant) or undoped. The semiconductor material of the substrate 110 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as single-layer, multi-layered, or gradient substrates may be used.

Further in FIG. 2A and FIG. 2B, a multi-layer stack 25 or “lattice” is formed over the substrate 110 of alternating layers of first semiconductor layers 21A, 21B, 21C (collectively referred to as first semiconductor layers 21) and second semiconductor layers 23, corresponding to act 1100 of FIG. 14. In some embodiments, the first semiconductor layers 21 may be formed of a first semiconductor material suitable for n-type nano-FETs, such as silicon, silicon carbide, or the like, and the second semiconductor layers 23 may be formed of a second semiconductor material suitable for p-type nano-FETs, such as silicon germanium or the like. Each of the layers of the multi-layer stack 25 may be epitaxially grown using a process such as chemical vapor deposition (CVD), atomic layer deposition (ALD), vapor phase epitaxy (VPE), molecular beam epitaxy (MBE), or the like.

Three layers of each of the first semiconductor layers 21 and the second semiconductor layers 23 are illustrated. In some embodiments, the multi-layer stack 25 may include one or two each or four or more each of the first semiconductor layers 21 and the second semiconductor layers 23. Although the multi-layer stack 25 is depicted as including a second semiconductor layer 23 as the bottommost layer, in some embodiments, the bottommost layer of the multi-layer stack 25 may be a first semiconductor layer 21.

Due to high etch selectivity between the first semiconductor materials and the second semiconductor materials, the second semiconductor layers 23 of the second semiconductor material may be removed without significantly removing the first semiconductor layers 21 of the first semiconductor material, thereby allowing the first semiconductor layers 21 to be patterned to form channel regions of nanostructure FETs. In some embodiments, the first semiconductor layers 21 are removed and the second semiconductor layers 23 are patterned to form channel regions. The high etch selectivity allows the first semiconductor layers 21 of the first semiconductor material to be removed without significantly removing the second semiconductor layers 23 of the second semiconductor material, thereby allowing the second semiconductor layers 23 to be patterned to form channel regions of nanostructure FETs.

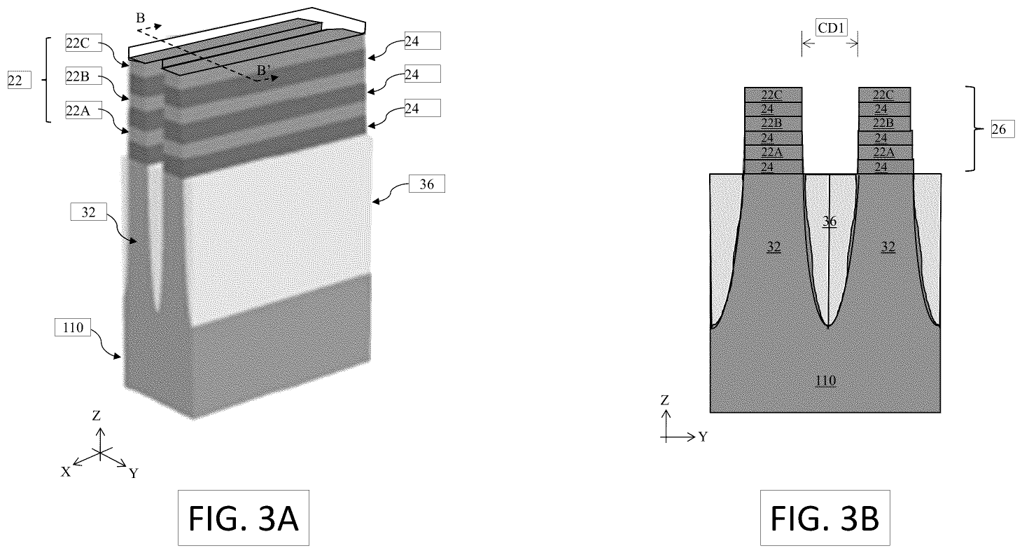

In FIG. 3A and FIG. 3B, fins 32 and vertical stacks 26 of nanostructures 22A, 22B, 22C, 24 are formed in the substrate 110 and the multi-layer stack 25 corresponding to act 1200 of FIG. 14. The nanostructures 22A-22C may be referred to collectively as the nanostructures 22. In some embodiments, the nanostructures 22, 24 and the fins 32 may be formed by etching trenches in the multi-layer stack 25 and the substrate 110. The etching may be any acceptable etch process, such as a reactive ion etch (RIE), neutral beam etch (NBE), the like, or a combination thereof. The etching may be anisotropic. First nanostructures 22A, 22B, 22C (also referred to as “channels” below) are formed from the first semiconductor layers 21, and second nanostructures 24 are formed from the second semiconductor layers 23. Distance CDI between adjacent fins 32 and nanostructures 22, 24 may be from about 18 nm to about 100 nm, less than 18 nm or greater than 100 nm. A portion of the device 10 is illustrated in FIGS. 3A and 3B including two fins 32 for simplicity of illustration. The process 1000 illustrated in FIGS. 2A-13F may be extended to any number of fins and is not limited to the two fins 32 shown in FIGS. 3A-13F. In some of the figures, three fins are depicted instead of two.

The fins 32 and the nanostructures 22, 24 may be patterned by any suitable method. For example, one or more photolithography processes, including double-patterning or multi-patterning processes, may be used to form the fins 32 and the nanostructures 22, 24. Generally, double-patterning or multi-patterning processes combine photolithography and self-aligned processes, allowing for pitches smaller than what is otherwise obtainable using a single, direct photolithography process. As an example of one multi-patterning process, a sacrificial layer may be formed over a substrate and patterned using a photolithography process. Spacers are formed alongside the patterned sacrificial layer using a self-aligned process. The sacrificial layer is then removed, and the remaining spacers may then be used to pattern the fins 32.

FIGS. 3A and 3B illustrate the fins 32 having tapered sidewalls, such that a width of each of the fins 32 and/or the nanostructures 22, 24 continuously increases in a direction towards the substrate 110. In such embodiments, each of the nanostructures 22, 24 may have a different width and be trapezoidal in shape. In other embodiments, the sidewalls are substantially vertical (non-tapered), such that width of the fins 32 and the nanostructures 22, 24 is substantially similar, and each of the nanostructures 22, 24 is rectangular in shape.

In FIGS. 3A and 3B, isolation regions 36, which may be shallow trench isolation (STI) regions, are formed adjacent the fins 32, corresponding to act 1300 of FIG. 14. The isolation regions 36 may be formed by depositing an insulation material over the substrate 110, the fins 32, and nanostructures 22, 24, and between adjacent fins 32 and nanostructures 22, 24. The insulation material may be an oxide, such as silicon oxide, a nitride, the like or a combination thereof, and may be formed by high-density plasma CVD (HDP-CVD), flowable CVD (FCVD), the like, or a combination thereof. In some embodiments, a liner (not separately illustrated) may first be formed along surfaces of the substrate 110, the fins 32, and the nanostructures 22, 24. Thereafter, the insulation material, such as those discussed above, may be formed over the liner.

The insulation material undergoes a removal process, such as a chemical mechanical polish (CMP), an etch-back process, combinations thereof, or the like, to remove excess insulation material over the nanostructures 22, 24. Top surfaces of the nanostructures 22, 24 may be exposed and level with the insulation material after the removal process is complete.

The insulation material is then recessed to form the isolation regions 36. After recessing, the nanostructures 22, 24 and upper portions of the fins 32 may protrude from between neighboring isolation regions 36. The isolation regions 36 may have top surfaces that are flat as illustrated, convex, concave, or a combination thereof. In some embodiments, the isolation regions 36 are recessed by an acceptable etching process, such as an oxide removal using, for example, dilute hydrofluoric acid (dHF), which is selective to the insulation material and leaves the fins 32 and the nanostructures 22, 24 substantially unaltered.

FIGS. 2A through 3B illustrate one embodiment (e.g., etch last) of forming the fins 32 and the nanostructures 22, 24. In some embodiments, the fins 32 and/or the nanostructures 22, 24 are epitaxially grown in trenches in a dielectric layer (e.g., etch first). The epitaxial structures may comprise the alternating semiconductor materials discussed above, such as the first semiconductor materials and the second semiconductor materials.

In some embodiments, the spacing between the channels 22A-22C (e.g., between the channel 22B and the channel 22A or the channel 22C) is in a range between about 8 nanometers (nm) and about 12 nm. In some embodiments, the spacing is less than 8 nm. In some embodiments, a thickness (e.g., measured in the Z-direction) of each of the channels 22A-22C is in a range between about 5 nm and about 8 nm. In some embodiments, the thickness is less than 5 nm. In some embodiments, a width (e.g., measured in the Y-direction) of each of the channels 22A-22C is at least about 8 nm. In some embodiments, the width is less than 8 nm.

Further in FIG. 3A and FIG. 3B, appropriate wells (not separately illustrated) may be formed in the fins 32, the nanostructures 22, 24, and/or the isolation regions 36. Using masks, an N-type impurity implant may be performed in P-type regions of the substrate 110, and a P-type impurity implant may be performed in N-type regions of the substrate 110. Example N-type impurities may include phosphorus, arsenic, antimony, or the like. Example P-type impurities may include boron, boron fluoride, indium, or the like. An anneal may be performed after the implants to repair implant damage and to activate the P-type and/or N-type impurities. In some embodiments, in situ doping during epitaxial growth of the fins 32 and the nanostructures 22, 24 may obviate separate implantations, although in situ doping and implantation doping may be used together.

In FIGS. 4A-4D, dummy or sacrificial gate structures 40 are formed over the fins 32 and/or the nanostructures 22, 24, corresponding to operation 1400 of FIG. 14. A sacrificial gate layer 45 is formed over the fins 32 and/or the nanostructures 22, 24. The sacrificial gate layer 45 may be made of materials that have a high etching selectivity versus the isolation regions 36. The sacrificial gate layer 45 may be a conductive, semiconductive, or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The sacrificial gate layer 45 may be deposited by physical vapor deposition (PVD), CVD, sputter deposition, or other techniques for depositing the selected material. A mask layer 47 is formed over the sacrificial gate layer 45, and may include, for example, silicon nitride, silicon oxynitride, or the like. The mask layer 47 may include one or more layers, such as a first mask layer and a second mask layer. The first mask layer may be formed in a first deposition process, and the second mask layer may be formed in a second deposition process following the first deposition process. In some embodiments, a gate dielectric layer 43 is formed before the sacrificial gate layer 45 between the sacrificial gate layer 45 and the fins 32 and/or the nanostructures 22, 24, as depicted in FIG. 4C.

A spacer layer or sidewall spacer 41 is formed over sidewalls of, and covering, the mask layer 47, the sacrificial gate layer 45 and the isolation regions 36, corresponding to operation 1500 of FIG. 14. The spacer layer 41 is made of an insulating material, such as SIN, SiO, SiCN, SiON, SiOCN, SiOC or the like, and may have a single-layer structure or a multi-layer structure including a plurality of dielectric layers, in accordance with some embodiments. The spacer layer 41 may be formed by depositing a spacer material layer (not shown) over the mask layer 47 and the sacrificial gate layer 45. In some embodiments, the spacer layer 41 includes one or more material layers. For example, the spacer layer 41 may include a first spacer layer 41A in contact with the sacrificial gate structures 40 and a second spacer layer 41B in contact with the first spacer layer 41A, as depicted in FIG. 4C and FIG. 4D. The first spacer layer 41A may be formed in a first deposition process, and the second spacer layer 41B may be formed in a second deposition process following the first deposition process.

As depicted in FIGS. 4A, 4C and 4D, portions of the spacer material layer between sacrificial gate structures 40 are not removed. For example, as depicted in FIG. 4D, horizontal portions of the spacer layer 41 are present over the isolation regions 36. Thickness of the spacer layer 41 may be in a range of about 5 nm to about 20 nm following deposition thereof. Although not depicted in a top view, the spacer layer 41 may cover the isolation regions 36. The spacer layer 41 may completely cover the isolation regions 36. In some embodiments, the spacer layer 41 substantially completely covers the isolation regions 36. For example, the spacer layer 41 may entirely cover each of the isolation regions 36, which is beneficial to provide protection of the isolation regions 36 during etching operations performed when forming source/drain openings and epitaxial layers that isolate channel(s) 22 from source/drain regions 82. In some embodiments, the first spacer layer 41A and the second spacer layer 41B cover the isolation regions 36 as just described. In some embodiments, the second spacer layer 41B may be removed from over the isolation regions 36, such that only the first spacer layer 41A covers the isolation regions 36. It should be understood that, as shown in FIG. 4D, the first and second spacer layers 41A, 41B may cover respective peripheral portions of the isolation regions 36 regardless of whether the second spacer layer 41B is removed from over, for example, respective central portions of the isolation regions 36.

FIGS. 4A-4C depict one process for forming the spacer layer 41. In some embodiments, additional spacer layers may be formed after removal of the sacrificial gate layer 45. In such embodiments, the sacrificial gate layer 45 is removed, leaving an opening, and the spacer layers may be formed by conformally coating material of the spacer layers along sidewalls of the opening. The conformally coated material may then be removed from the bottom of the opening corresponding to the top surface of the uppermost channel, e.g., the channel 22A, prior to forming an active gate, such as the gate structure 200.

FIGS. 4E-4H depict formation of a mask layer 400 over the isolation regions 36, corresponding to operation 1600 of FIG. 14. The mask layer 400 may be or include a photoresist, a bottom antireflective coating (BARC), other mask material, combinations thereof or the like. The mask layer 400 will be described as a BARC layer 400 in the following. The BARC layer 400 may be deposited using a spin-coating method. Initially, a thin layer of BARC material may be deposited onto the surface of the substrate using a spin-coater, then the substrate may be spun at a high speed to spread the material evenly over the surface. After the BARC material has been applied, the BARC material may be cured by heating to a selected temperature for a selected amount of time, which may be beneficial to adhere the BARC material to the substrate and achieve selected optical properties. The cured BARC material may be the BARC layer 400, which is shown in FIGS. 4E and 4F.

After curing, an optional layer of photoresist material may be applied on top of the BARC layer 400 (not depicted in the figures). The photoresist material may then be patterned using lithography, which exposes selected areas of the photoresist to light. Exposed or unexposed areas of the photoresist may then be removed using a developer solution, leaving a patterned photoresist layer on top of the BARC layer. The BARC layer 400 may include one or more materials, such as one or more organic BARCs, one or more inorganic BARCs, hybrid BARCs, combinations thereof or the like. Organic BARCs can include polymeric materials, such as polyimides, poly(methyl methacrylate) (PMMA), or novolacs. Inorganic BARCs can include metal oxides, such as silicon oxide (SiOx) or titanium oxide (TiOx). Hybrid BARCs can include one or more combinations of organic and inorganic materials, such as silsesquioxanes or organometallic polymers.

In FIGS. 4G and 4H, the BARC layer 400 is recessed. The BARC layer 400 may be recessed by a wet or dry etching operation. Wet etching can involve using a chemical solution to remove the BARC material from selected areas of the substrate. Dry etching can involve using plasma-based techniques, such as reactive ion etching (RIE) or plasma etching, to remove the BARC material. In FIGS. 4G and 4H, the BARC layer 400 is recessed uniformly. In some embodiments, the BARC layer 400 is recessed based on a pattern. After the BARC recess process is complete, a cleaning operation may be performed to remove any remaining BARC material or etchant residue. The BARC layer 400 may be recessed to a level below an uppermost surface of the channels 22, such that the spacer layer 41 over the sacrificial gate structures 40 and over at least the uppermost channels 22C is exposed, corresponding to operation 1700 of FIG. 14. In some embodiments, the BARC layer 400 is recessed to a level lower than that depicted in FIG. 4H. For example, the BARC layer 400 may be recessed to a level below the bottom surface of the uppermost channels 22C or to a level below the top or bottom surface of the middle channels 22B. After recessing the BARC layer 400, tops of the vertical stacks 26 may be exposed from the BARC layer 400, but may still be covered by the spacer layer 41.

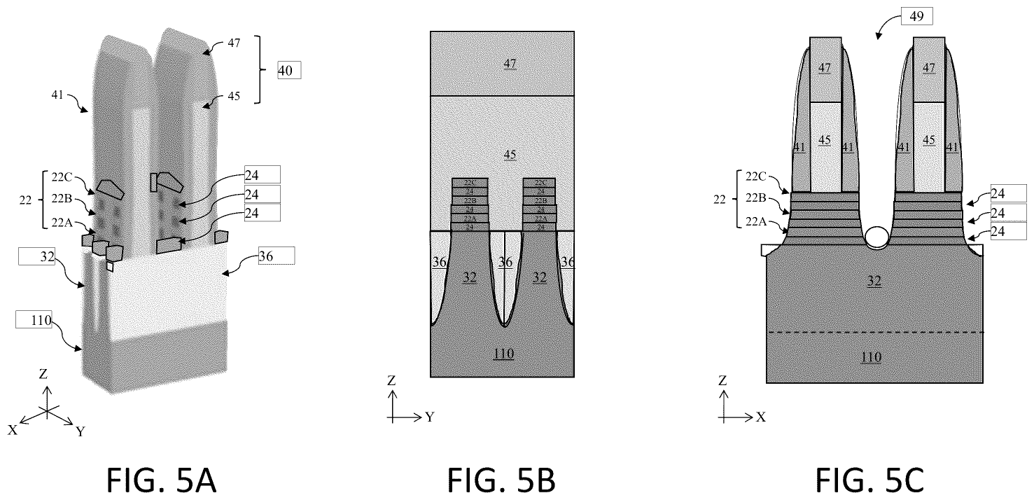

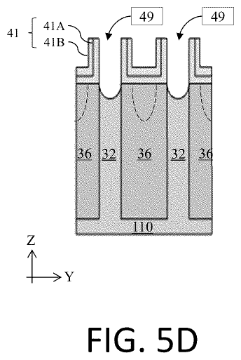

In FIGS. 5A-5D, an etching process that includes one or more etching operations is performed to etch the portions of protruding fins 32 and/or nanostructures 22, 24 that are not covered by sacrificial gate structures 40, resulting in the structure shown. For example, a first etching operation may recess and/or remove exposed portions of the spacer layer 41 over the sacrificial gate structure 40 and over upper portions of the stacks 26 not covered by the BARC layer 400 (see FIG. 4D). Following the first etching operation, a second etching operation may be performed that removes exposed portions of the stacks 26, resulting in the structure shown in FIGS. 5A, 5C and 5D. The recessing forms source/drain openings 49 between neighboring stacks of channels 22 that are over the same fin 32, corresponding to operation 1800 of FIG. 14. The recessing may be anisotropic, such that the portions of fins 32 directly underlying sacrificial gate structures 40 and the spacer layer 41 are protected and are not etched. The top surfaces of the recessed fins 32 may be substantially coplanar with the top surfaces of the isolation regions 36, in accordance with some embodiments. As depicted in FIG. 5D, the top surfaces of the recessed fins 32 may be concave and somewhat lower than the top surfaces of the isolation region 36. FIG. 5C shows two vertical stacks 26 of nanostructures 22, 24 following the etching process for simplicity. In general, the etching process may be used to form any selected number of vertical stacks 26 of nanostructures 22, 24 over the fins 32. As shown in FIG. 5D, due to the spacer layer 41 covering the isolation regions 36, the etching that forms the source/drain openings does not substantially attack the isolation regions 36, such that the isolation regions 36 protect sidewalls of the fins 32. Dashed lines in FIG. 5D depict conceptually that portions of the isolation regions 36 would be removed by the etching process were the spacer layer 41 not positioned over the isolation regions 36 as described herein.

Following formation of the source/drain openings 49, the mask such as the BARC layer 400 is removed, corresponding to operation 1900 of FIG. 14.

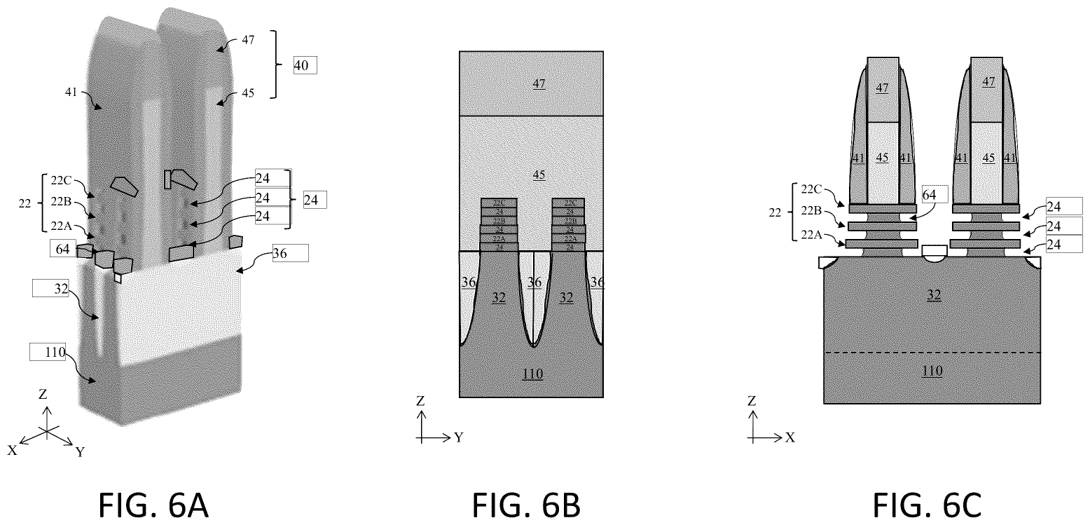

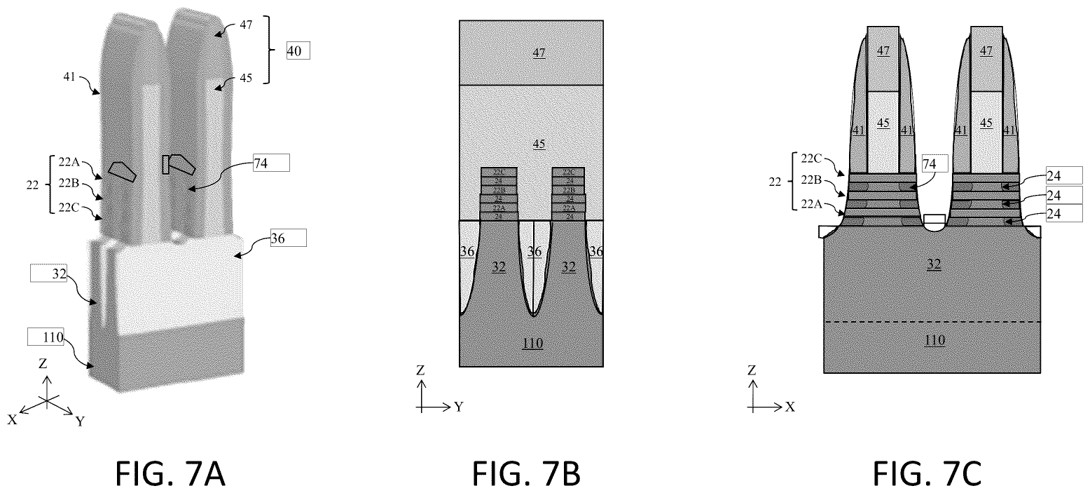

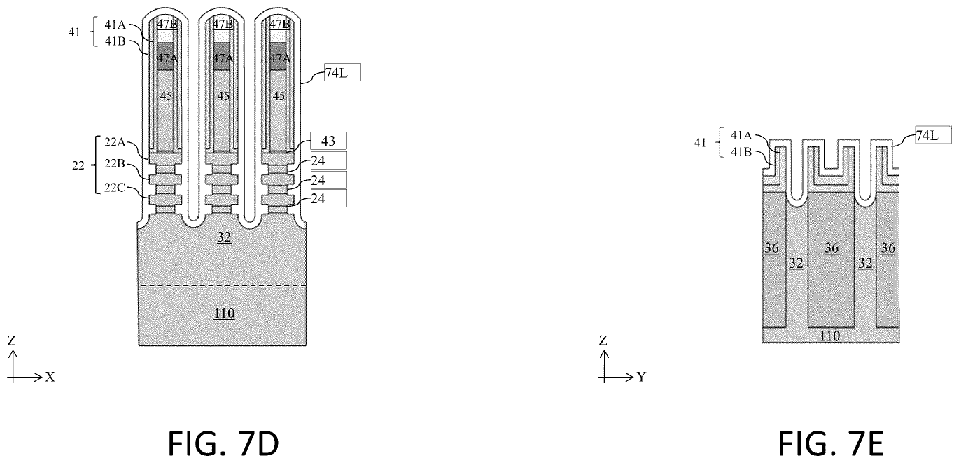

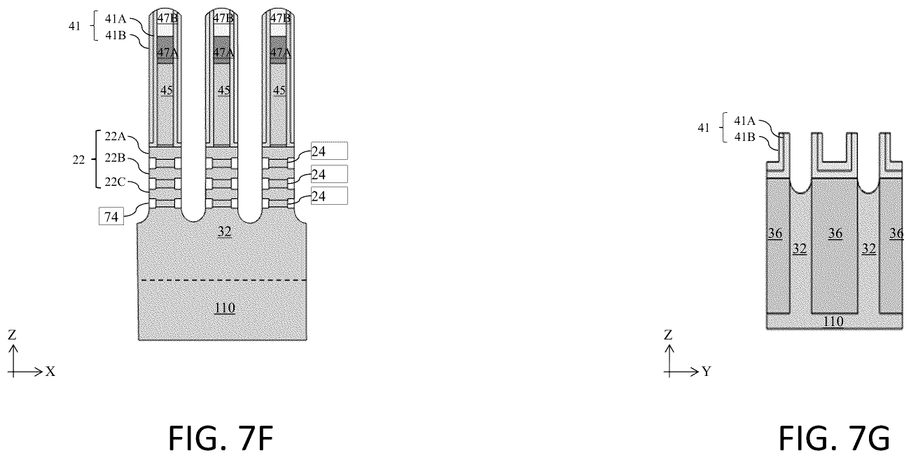

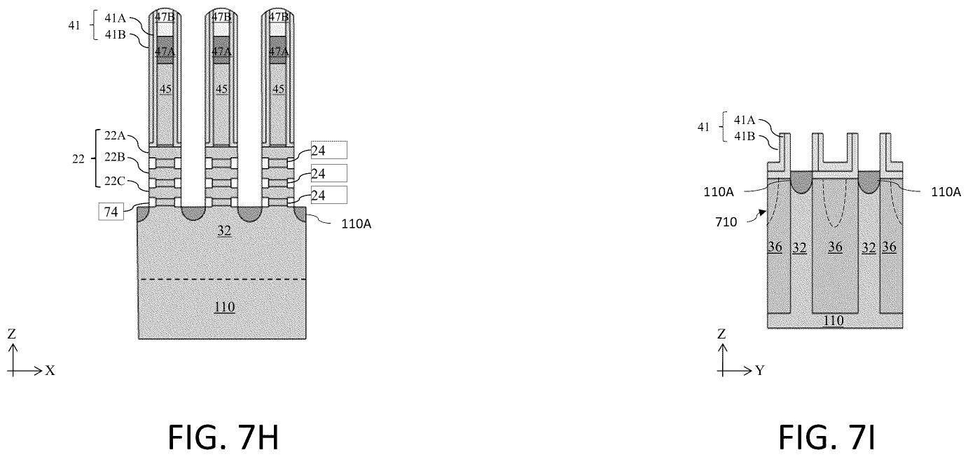

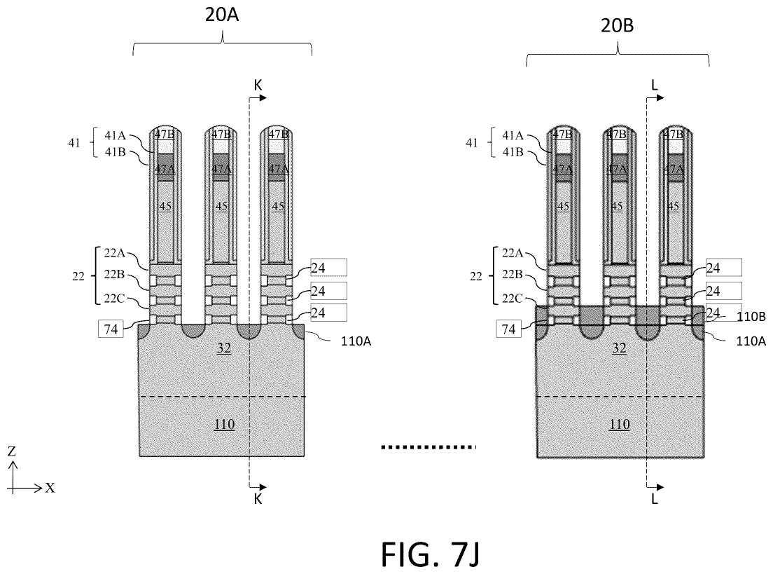

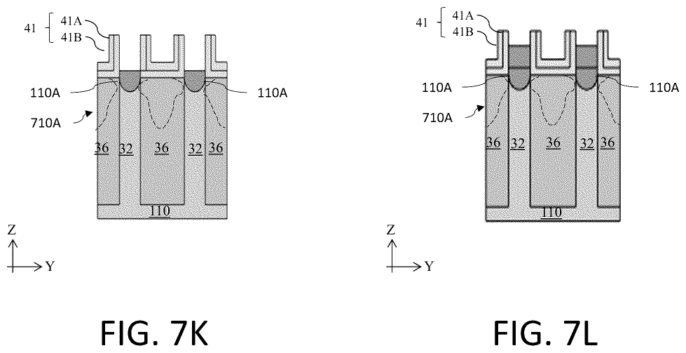

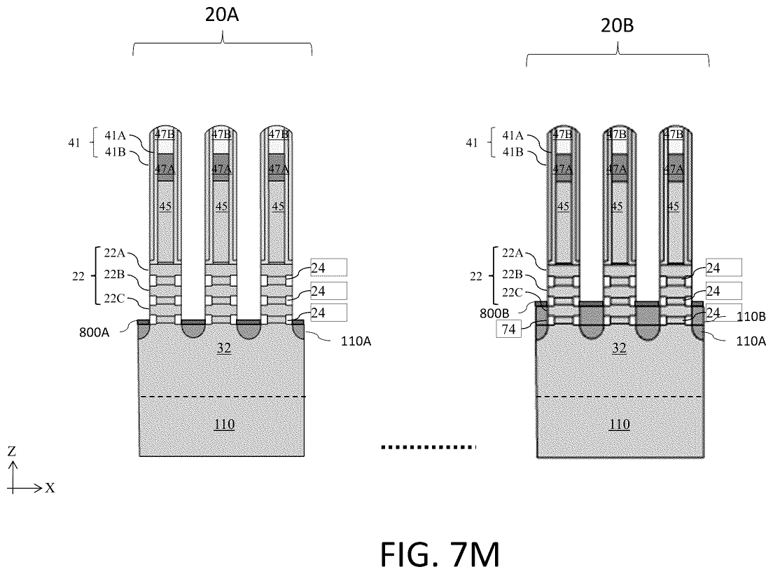

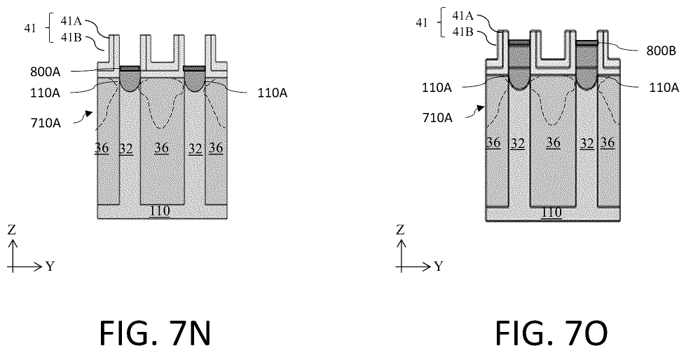

FIGS. 6A-6C and 7A-7G illustrate formation of inner spacers 74, corresponding to operation 2000 of FIG. 14. A selective etching process is performed to recess end portions of the nanostructures 24 exposed by openings in the spacer layer 41 without substantially attacking the nanostructures 22, which is depicted in FIGS. 6A-6C. After the selective etching process, recesses 64 are formed in the nanostructures 24 at locations where the removed end portions used to be. The resulting structure is shown in FIGS. 6A-6C.

Next, an inner spacer layer 74L is formed to fill (e.g., partially or fully) the recesses 64 in the nanostructures 22 formed by the previous selective etching process, which is depicted in FIGS. 7D and 7E. The inner spacer layer 74L may be a suitable dielectric material, such as silicon carbon nitride (SiCN), silicon oxycarbonitride (SiOCN), or the like, formed by a suitable deposition method such as PVD, CVD, ALD, or the like. An etching process, such as an anisotropic etching process, is performed to remove portions of the inner spacer layers disposed outside the recesses in the nanostructures 24. The remaining portions of the inner spacer layers (e.g., portions disposed inside the recesses 64 in the nanostructures 24) form the inner spacers 74. The resulting structure is shown in FIGS. 7A-7C, 7F and 7G.

FIGS. 7H-70 are diagrammatic cross-sectional side views that depict formation of epitaxial layers 110A, 110B and bottom dielectric layer 800B in accordance with various embodiments. The epitaxial layers 110A, 110B isolate one or more of the channels 22A-22C, corresponding to operation 2100 of FIG. 14.

In FIGS. 7H, 7I, following formation of the source/drain openings 49 and the inner spacers 74, the source/drain openings 49 extend below the upper surface of the fins 32. In some embodiments, a first epitaxial layer 110A is formed in a portion of the source/drain openings 49 below the level of the upper surface of the fins 32, as shown in FIG. 7H. The first epitaxial layer 110A may be an undoped semiconductor layer, such as an undoped silicon layer. The undoped silicon layer 110A may be grown in an epitaxial chamber using a process such as chemical vapor deposition (CVD). In the CVD, a silicon source gas, such as silane (SiH₄), may be introduced into a heated chamber along with a carrier gas, such as hydrogen (H₂). The gases react on the surface of the fins 32, which may be heated to a temperature between about 900° C. to 1100° C. During the reaction, the silicon source gas decomposes and releases silicon atoms, which then diffuse onto the surface of the fins 32 and form a single crystal layer of silicon. A low-pressure environment may be beneficial to reduce presence of impurities and improve deposition rate uniformity. To grow undoped silicon, no additional dopant gases are introduced into the chamber. The resulting layer has low level of impurities and is electrically neutral, such that the first epitaxial layer 110A may be an insulator layer. Formation of the first epitaxial layer 110A may be global, meaning that, for example, no mask is present on the IC chip 10 while the CVD is ongoing.

FIG. 7J is a diagrammatic cross-sectional view of first and second device regions 20A, 20B of IC chip 10 in accordance with various embodiments. FIGS. 7K, 7L are diagrammatic cross-sectional views along lines K-K, L-L, respectively. In FIGS. 7J, 7K, 7L, following formation of the first epitaxial layer 110A, a second epitaxial layer 110B is formed in a portion of the source/drain openings 49 located in the second device region 20B. The second epitaxial layer 110B may be an undoped semiconductor layer, such as an undoped silicon layer, and formation thereof may be similar to formation of the first epitaxial layer 110A. The second epitaxial layer 110B may extend from the top of the fin 32 to a level that is above one or more of the channels 22, so as to isolate the one or more channels electrically and/or physically from source/drain regions 82 formed in a subsequent process. For example, as shown in FIG. 7J, the second epitaxial layer 110B extends to a level that is above the bottommost channels 22C. In some embodiments, the second epitaxial layer 110B may extend to any level that is above the bottommost channels 22C and below the uppermost channels 22A.

During formation of the second epitaxial layer 110B, the first device region 20A may be masked. For example, a hard mask may cover the first device region 20A. The hard mask may include AlOx or another suitable material. Following formation of the second epitaxial layer 110B, the hard mask may be removed.

In FIGS. 7M, 7N, 70, following formation of the first and second epitaxial layers 110A, 110B, a bottom dielectric layer is formed. The bottom dielectric layer or flexible bottom insulator (“FBI”) is beneficial to prevent mesa leakage current in the IC chip 10. The bottom dielectric layer includes a first bottom dielectric layer 800A that is formed on the first epitaxial layer 110A in the first device region 20A and a second bottom dielectric layer 800B that is formed on the second epitaxial layer 110B in the second device region 20B. The first bottom dielectric layer 800A may be in direct contact with the first epitaxial layer 110A, and the second bottom dielectric layer 800B may be in direct contact with the second epitaxial layer 110B. The bottom dielectric layer including the first and second bottom dielectric layers 800A, 800B may be formed in the same deposition operation, such that the first and second bottom dielectric layers 800A, 800B are the same material and the same thickness. The bottom dielectric layer may include SiN, SiOC, SiOCN, SiCN, combinations thereof or the like. In some embodiments, the bottom dielectric layer may have thickness in a range of about 1 nm to about 5 nm. In some embodiments, the bottom dielectric layer has thickness greater than 5 nm.

FIGS. 7N, 70 depict by dashed lines regions 710A of the isolation regions 36 that would be removed by the etching processes described herein were the spacer layer 41 not covering the isolation regions 36 during formation of the source/drain openings 49 and the first and second epitaxial layers 110A, 110B.

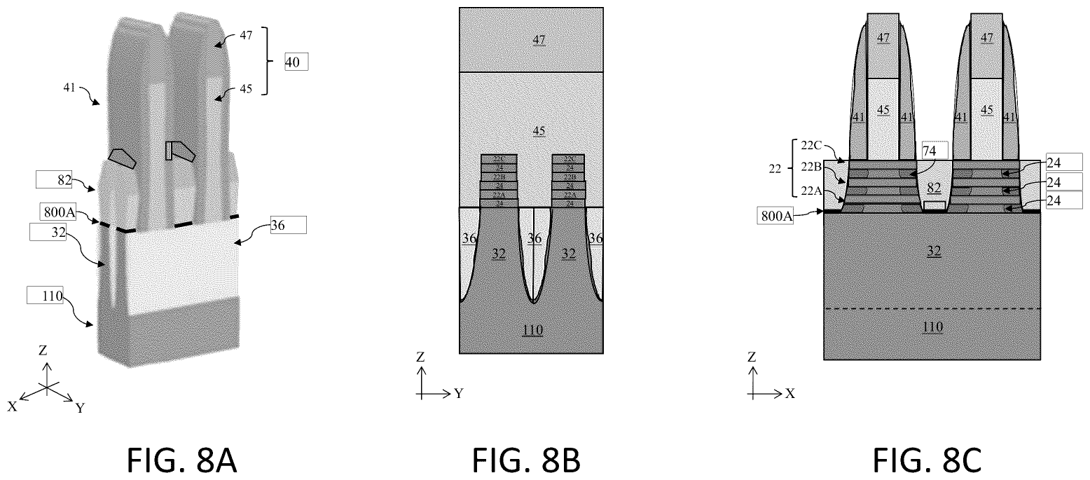

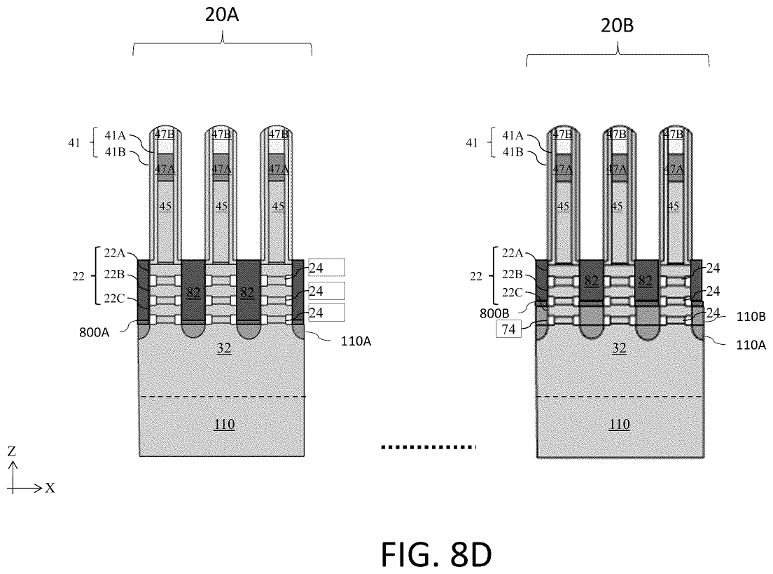

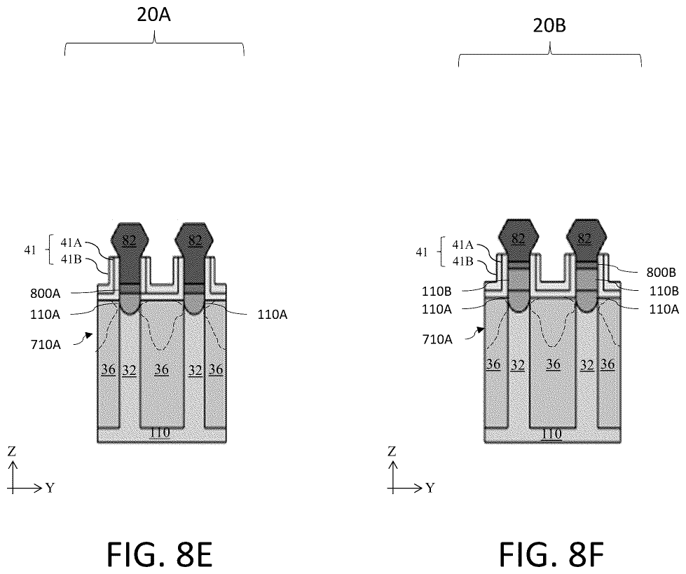

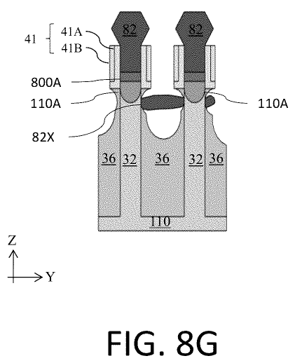

FIGS. 8A-8G illustrate formation of source/drain regions 82 corresponding to act 2200 of FIG. 14. Source/drain region(s) may refer to a source or a drain, individually or collectively dependent upon the context. In the illustrated embodiment, the source/drain regions 82 are epitaxially grown from epitaxial material(s). In some embodiments, the source/drain regions 82 exert stress in the respective channels 22A-22C, thereby improving performance. The source/drain regions 82 are formed such that each sacrificial gate structure 40 is disposed between respective neighboring pairs of the source/drain regions 82. In some embodiments, the spacer layer 41 separates the source/drain regions 82 from the sacrificial gate layer 45 by an appropriate lateral distance to prevent electrical bridging to subsequently formed gates of the resulting device.

The source/drain regions 82 may include any acceptable material, such as appropriate for n-type or p-type devices. For n-type devices, the source/drain regions 82 include materials exerting a tensile strain in the channel regions, such as silicon, SiC, SiCP, SiP, or the like, in some embodiments. When p-type devices are formed, the source/drain regions 82 include materials exerting a compressive strain in the channel regions, such as SiGe, SiGeB, Ge, GeSn, or the like, in accordance with certain embodiments. The source/drain regions 82 may have surfaces raised from respective surfaces of the fins and may have facets. Neighboring source/drain regions 82 may merge in some embodiments to form a singular source/drain region 82 adjacent two neighboring fins 32.

In some embodiments, a first epitaxial growth process may be performed to form n-type source/drain regions 82 and a second epitaxial growth process may be performed to form p-type source/drain regions 82. It should be understood that “first” and “second” can be interchanged in this context. For example, n-type epitaxial growth may precede or follow p-type epitaxial growth.

The source/drain regions 82 may be implanted with dopants followed by an anneal. The source/drain regions may have an impurity concentration of between about 1019 cm⁻³ and about 1021 cm⁻³. N-type and/or p-type impurities for source/drain regions 82 may be any of the impurities previously discussed. In some embodiments, the source/drain regions 82 are in situ doped during growth. A contact etch stop layer (CESL) and interlayer dielectric (ILD), not illustrated for simplicity in FIGS. 8A-8C, may then be formed covering the sacrificial gate structures 40 and the source/drain regions 82.

As shown in FIG. 8D, source/drain regions 82 in the first device region 20A are in contact with all three channels 22A, 22B, 22C and source/drain regions 82 in the second device region 20B are in contact with fewer than all three channels 22A, 22B, 22C (e.g., channels 22B, 22C and not channels 22A). As such, effective width Weff in the first device region 20A exceeds that in the second device region 20B.

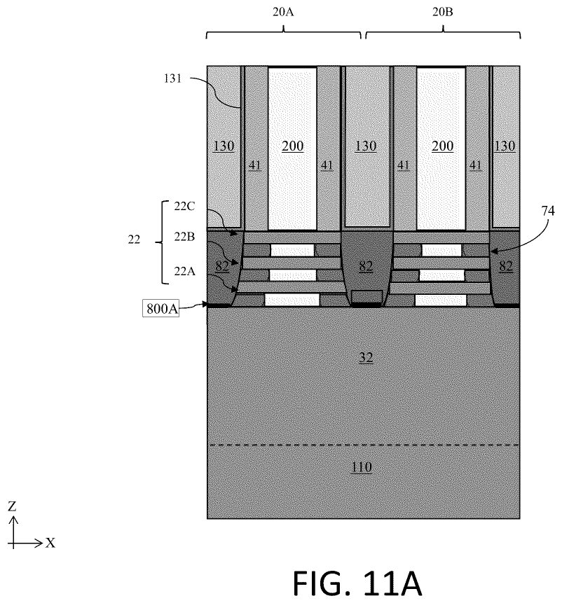

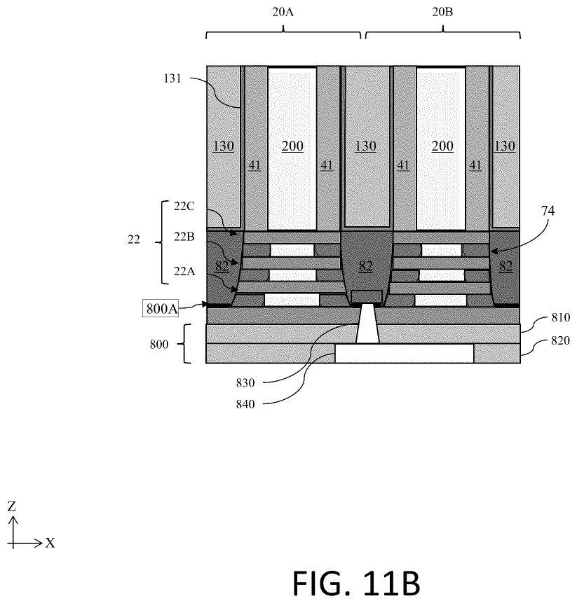

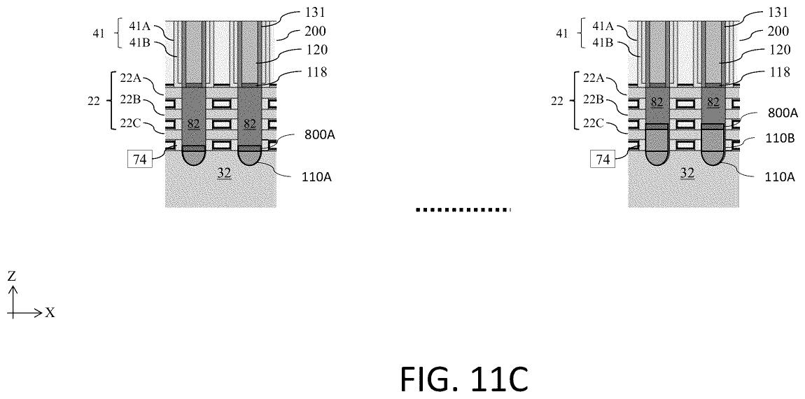

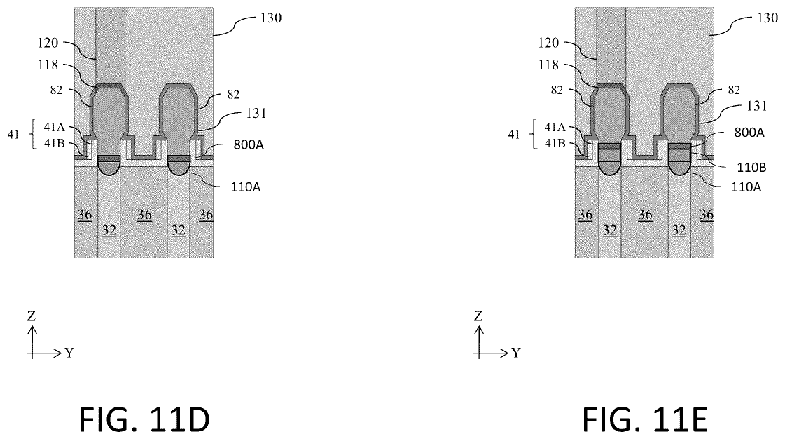

FIGS. 8E, 8F are diagrammatic cross-sectional side views in the YZ plane of the source/drain regions 82 on the fins 32 in accordance with various embodiments. The source/drain regions 82 in the first device region 20A may have larger height in the Z-axis direction than the source/drain regions 82 in the second device region 20B. Although not specifically depicted in FIGS. 8E, 8F, the source/drain region 82 in the first device region 20A may have different profile than the source/drain region 82 in the second device region 20B other than height in the Z-axis direction as just described. For example, the source/drain region 82 in the first device region 20A may have different bottom shape than the source/drain region 82 in the second device region 20B, such as longer or shorter bottom shape in the Y-axis direction and/or the X-axis direction. In another example, the bottom profile of the source/drain region 82 in the first device region 20A may have different concavity or convexity than the bottom profile of the source/drain region 82 in the second device region 20B. The spacer layers 41A, 41B constrain lateral growth of the source/drain regions 82, whereas the source/drain regions 82 may have lateral portions above the spacer layers 41A, 41B, as shown. As depicted in FIGS. 1B, 1C, 11D, 11E, the spacer layers 41A, 41B may be present in the IC device 10 instead of being removed. Namely, the spacer layers 41A, 41B may be present in a final product or structure that includes the IC device 10. In some embodiments, the spacer layers 41A, 41B may be removed, for example, prior to depositing the ESL 131 and ILD 130 (see FIGS. 1A-1C, 11A).

FIG. 8G is a diagrammatic cross-sectional side view that depicts epitaxial mushrooming and/or bridging when sidewalls of the fins 32 are exposed due to etching of the isolation regions 36 when the spacer layer 41 is not present over the respective central portions of the isolation regions 36. For example, a mushroom portion 82X may grow laterally from one or both of the fins 32 depicted in FIG. 8G during epitaxial growth of the source/drain regions 82.

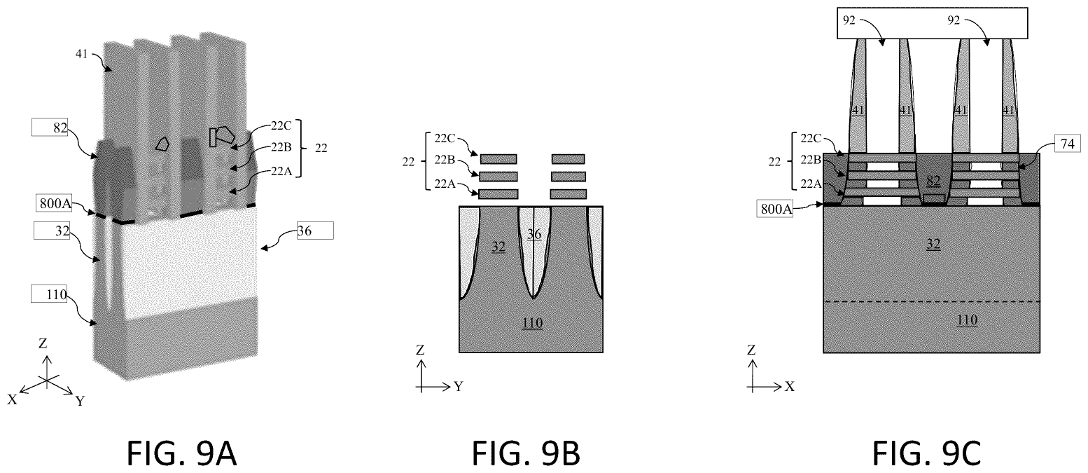

In FIGS. 9A-9C, following formation of the source/drain regions 82, fin channels 22A-22C are released by removal of the nanostructures 24, the mask layer 47, and the sacrificial gate layer 45. A planarization process, such as a CMP, is performed to level the top surfaces of the sacrificial gate layer 45 and gate spacer layer 41. The planarization process may also remove the mask layer 47 on the sacrificial gate layer 45, and portions of the gate spacer layer 41 along sidewalls of the mask layer 47. Accordingly, the top surfaces of the sacrificial gate layer 45 are exposed.

Next, the sacrificial gate layer 45 is removed in an etching process, so that recesses 92 are formed. In some embodiments, the sacrificial gate layer 45 is removed by an anisotropic dry etch process. For example, the etching process may include a dry etch process using reaction gas(es) that selectively etch the sacrificial gate layer 45 without etching the spacer layer 41. The sacrificial gate dielectric 43, when present, may be used as an etch stop layer when the sacrificial gate layer 45 is etched. The sacrificial gate dielectric 43 may then be removed after the removal of the sacrificial gate layer 45.

The nanostructures 24 are removed to release the nanostructures 22. After the nanostructures 24 are removed, the nanostructures 22 form a plurality of nanosheets that extend horizontally (e.g., parallel to a major upper surface of the substrate 110) and are stacked vertically. The nanosheets may be collectively referred to as the channels 22 of a nanostructure device, such as a nanosheet FET (NSFET), which may be a GAAFET.

In some embodiments, the nanostructures 24 are removed by a selective etching process using an etchant that is selective to the material of the nanostructures 24, such that the nanostructures 24 are removed without substantially attacking the nanostructures 22. In some embodiments, the etching process is an isotropic etching process using an etching gas, and optionally, a carrier gas, where the etching gas comprises F₂ and HF, and the carrier gas may be an inert gas such as Ar, He, N₂, combinations thereof, or the like.

In some embodiments, the nanostructures 24 are removed and the nanostructures 22 are patterned to form channel regions of both PFETs and NFETs. However, in some embodiments the nanostructures 24 may be removed and the nanostructures 22 may be patterned to form channel regions of a first nanostructure device, and nanostructures 22 may be removed and the nanostructures 24 may be patterned to form channel regions of a second nanostructure device. In some embodiments, the nanostructures 22 may be removed and the nanostructures 24 may be patterned to form channel regions of a first nanostructure device, and the nanostructures 24 may be removed and the nanostructures 22 may be patterned to form channel regions of a second nanostructure device. In some embodiments, the nanostructures 22 may be removed and the nanostructures 24 may be patterned to form channel regions of both PFETs and NFETs.

In some embodiments, the nanosheets 22 of the nanostructure devices are reshaped (e.g., thinned) by a further etching process to improve gate fill window. The reshaping may be performed by an isotropic etching process selective to the nanosheets 22. After reshaping, the nanosheets 22 may exhibit a dog bone shape in which middle portions of the nanosheets 22 are thinner than peripheral portions of the nanosheets 22 along the X direction.

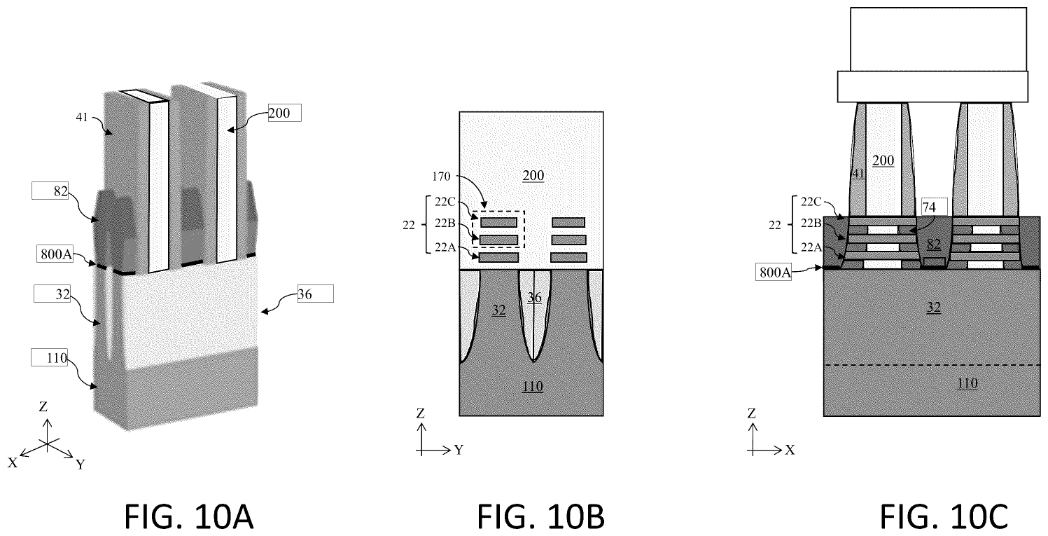

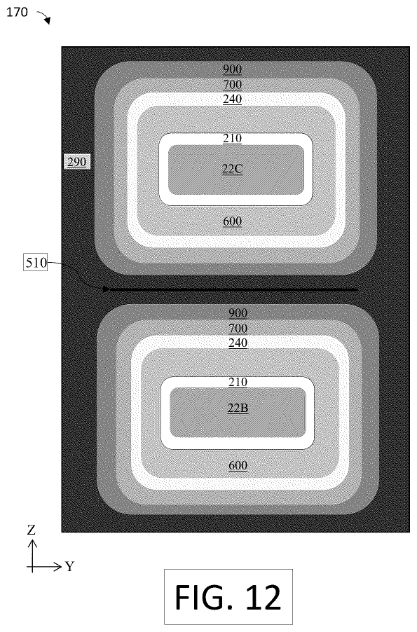

Next, in FIGS. 10A-10C, replacement gates 200, such as the gate structure 200, are formed. Each replacement gate 200 generally includes an interfacial layer (IL) 210, a gate dielectric layer 600 and a gate fill layer 290 (see FIG. 12). In some embodiments, the replacement gate 200 further includes work function metal layers. Formation of the gate structures 200 is described in greater detail with reference to FIG. 12.

FIG. 11A shows the semiconductor device including an interlayer dielectric (ILD) 130 and an etch stop layer (ESL) 131. The ILD 130 provides electrical isolation between the various components of the semiconductor device discussed above, for example between the gate structure 200 and a subsequently formed source/drain contact. The etch stop layer 131 may be formed prior to forming the ILD 130 and may be positioned laterally between the ILD 130 and the gate spacers 41 and vertically between the ILD 130 and the source/drain features 82. In some embodiments, insulating materials that form the ILD 130 may comprise silicon oxide, phosphosilicate glass (PSG), borosilicate glass (BSG), boron-doped phosphosilicate glass (BPSG), undoped silicate glass (USG), a low dielectric constant (low-k) dielectric such as, fluorosilicate glass (FSG), silicon oxycarbide (SiOCH), carbon-doped oxide (CDO), flowable oxide, or porous oxides (e.g., xerogels/aerogels), or the like, or a combination thereof. The dielectric material used to form the ILD 130 may be deposited using any suitable method, such as CVD, physical vapor deposition (PVD), ALD, PEALD, PECVD, SACVD, FCVD, spin-on, and/or the like, or a combination thereof. In some embodiments, the etch stop layer 131 is or includes a dielectric material, such as SIN, SiCN, SiC, SiOC, SiOCN, HfO₂, ZrO₂, ZrAlOx, HfAlOx, HfSiOx, Al₂O₃, or other suitable material. The dielectric material used to form the ESL 131 may be deposited using any suitable method, such as CVD, PVD, ALD, PEALD, PECVD, SACVD, FCVD, spin-on, and/or the like, or a combination thereof. In some embodiments, thickness of the etch stop layer 131 is in a range of about 1 nm to about 5 nm.

FIG. 11B shows the semiconductor device including backside interconnect structure 800 in accordance with various embodiments. Frontside interconnect features are omitted from view in FIG. 11B for clarity of illustration. In some embodiments, following formation of frontside interconnect features, the substrate 110 is thinned or removed, and the fins 32 are thinned or removed. Following thinning of the substrate 110, and optionally the fins 32, the backside interconnect structure 800 is formed. A first backside ILD 810 may be formed on the backside of the semiconductor device. Materials and formation processes may be similar to those described with reference to the ILD 130. Then, a first removal operation, such as an etching operation, may be performed to pattern the first backside ILD 810 and optionally the fins 32 to form first openings that expose one or more of the source/drain regions 82. A first backside via or contact 830 is formed in one of the openings and contacts the backside of the source/drain region 82. In some embodiments, a silicide is formed between the first backside contact 830 and the source/drain region 82. A second backside ILD 820 is formed on the first backside ILD 810. Materials and formation processes may be similar to those described with reference to the ILD 130. Second openings are formed in the second backside ILD 820 by a second removal process, such as a second etching operation, that patterns the second backside ILD 820. A first backside trace or wire 840 is formed in the second opening. Formation of the first backside contact 830 may be similar in many respects to formation of the contacts 120.

FIGS. 11C, 11D, 11E illustrate formation of the source/drain contacts 120 in accordance with various embodiments. The source/drain contacts 120 may include a conductive material such as tungsten, ruthenium, cobalt, copper, titanium, titanium nitride, tantalum, tantalum nitride, iridium, molybdenum, nickel, aluminum, or combinations thereof. The source/drain contacts 120 may be surrounded by barrier layers (not shown), such as SiN or TiN, which help prevent or reduce diffusion of materials from and into the contacts 120. A silicide layer 118 may also be formed between the source/drain features 82 and the source/drain contacts 120, so as to reduce source/drain contact resistance. The silicide layer 118 includes nickel, cobalt, titanium, tantalum, platinum, tungsten, other noble metals, other refractory metals, rare earth metals or their alloys. In some embodiments, thickness of the silicide layer (in the Z-axis direction) is in a range of about 0.5 nm to about 5 nm. In some embodiments, height of the source/drain contacts 120 may be in a range of about 1 nm to about 50 nm.

FIGS. 11D, 11E depict that the second spacer layer 41B may be thinned or removed over the isolation regions 36 due to the etching process(es) that forms the source/drain openings 49, the first and second epitaxial layers 110A, 110B, the bottom dielectric layers 800A, 800B and the source/drain regions 82. For example, when formed, the spacer layer 41 may have thickness in a range of about 5 nm to about 20 nm. In some embodiments, one or more of materials of the spacer layer 41, the ILD 130 and the CESL 131 are different from each other or the same as each other. Generally, the ILD 130 and the CESL 131 are different materials. In some embodiments, the spacer layer 41 may be the same material as either the ILD 130 or the CESL 131. In some embodiments, all three of the spacer layer 41, the ILD 130 and the CESL 131 are different materials from each other. Then, when the CESL 131 is formed, the horizontal portion of the spacer layer 41 over the isolation regions 36 may have thickness in a range of about 2 nm to about 8 nm. When the second spacer layer 41B is removed over the isolation regions 36, one or more openings may be present in the second spacer layer 41B. The one or more openings may overlap the upper surface of the isolation region 36. In some embodiments, the first spacer layer 41B underneath the one or more openings may be recessed. In some embodiments, the first spacer layer 41B is removed, such that one or more openings is present that exposes the upper surface of the isolation region 36. In some embodiments, the spacer layer 41 over the isolation regions 36 is not substantially thinned or removed during formation of the source/drain openings 49, the first and second epitaxial layers 110A, 110B, the bottom dielectric layers 800A, 800B and the source/drain regions 82.

FIG. 12 is a diagrammatic cross-sectional side view of a region 170 of FIG. 10B in accordance with various embodiments. The gate structure 200 is disposed over and between the channels 22A-22C, respectively. The gate structure 200 may wrap around each of the channels 22A-22C. In some embodiments, the gate structure 200 is disposed over and between the channels 22A-22C, which may be silicon channels for N-type devices or silicon germanium channels for P-type devices, or may be silicon channels for both N-type and P-type devices. In some embodiments, the gate structure 200 includes the interfacial layer (IL) 210, one or more gate dielectric layers 600, one or more work function tuning layers 900, and a metal fill layer 290.

The interfacial layer 210, which may be an oxide of the material of the channels 22A-22C, is formed on exposed areas of the channels 22A-22C and the top surface of the fin 32. The interfacial layer 210 promotes adhesion of the gate dielectric layers 600 to the channels 22A-22C. In some embodiments, the interfacial layer 210 has thickness of about 5 Angstroms (A) to about 50 Angstroms (A). In some embodiments, the interfacial layer 210 has thickness of about 10 A. The interfacial layer 210 having thickness that is too thin may exhibit voids or insufficient adhesion properties. The interfacial layer 210 being too thick consumes gate fill window, which is related to threshold voltage tuning and resistance as described above. In some embodiments, the interfacial layer 210 is doped with a dipole, such as lanthanum, for threshold voltage tuning.

The gate dielectric layer 600 may be formed on the IL 210. In some embodiments, the gate dielectric layer 600 includes at least one high-k gate dielectric material, which may refer to dielectric materials having a high dielectric constant that is greater than a dielectric constant of silicon oxide (k≈3.9). Exemplary high-k dielectric materials include HfO₂, HfSiO, HfSiON, HfTaO, HfTiO, HfZrO, ZrO₂, Ta₂O₅, or combinations thereof. In some embodiments, the gate dielectric layer 600 has thickness of about 5 A to about 100 A.

In some embodiments, the gate dielectric layer 600 may include dopants, such as metal ions driven into the high-k gate dielectric from La₂O₃, MgO, Y₂O₃, TiO₂, Al₂O₃, Nb₂O₅, or the like, or boron ions driven in from B₂O₃, at a concentration to achieve threshold voltage tuning. As one example, for N-type transistor devices, lanthanum ions in higher concentration reduce the threshold voltage relative to layers with lower concentration or devoid of lanthanum ions, while the reverse is true for P-type devices. In some embodiments, the gate dielectric layer 600 of certain transistor devices (e.g., IO transistors) is devoid of the dopant that is present in certain other transistor devices (e.g., N-type core logic transistors or P-type IO transistors). In N-type IO transistors, for example, relatively high threshold voltage is desirable, such that it may be preferable for the IO transistor high-k dielectric layers to be free of lanthanum ions, which would otherwise reduce the threshold voltage.

In some embodiments, the gate structure 200 further includes one or more work function metal layers, represented collectively as work function metal layer 900. When configured as an NFET, the work function metal layer 900 of the GAA device 20 may include at least an N-type work function metal layer, an in-situ capping layer, and an oxygen blocking layer. In some embodiments, the N-type work function metal layer is or comprises an N-type metal material, such as TiAIC, TiAl, TaAIC, TaAl, or the like. The in-situ capping layer is formed on the N-type work function metal layer, and may comprise TIN, TiSiN, TaN, or another suitable material. The oxygen blocking layer is formed on the in-situ capping layer to prevent oxygen diffusion into the N-type work function metal layer, which would cause an undesirable shift in the threshold voltage. The oxygen blocking layer may be formed of a dielectric material that can stop oxygen from penetrating to the N-type work function metal layer, and may protect the N-type work function metal layer from further oxidation. The oxygen blocking layer may include an oxide of silicon, germanium, SiGe, or another suitable material. In some embodiments, the work function metal layer 900 includes more or fewer layers than those described.

The work function metal layer 900 may further include one or more barrier layers comprising a metal nitride, such as TIN, WN, MON, TaN, or the like. Each of the one or more barrier layers may have thickness ranging from about 5 A to about 20 A. Inclusion of the one or more barrier layers provides additional threshold voltage tuning flexibility. In general, each additional barrier layer increases the threshold voltage. As such, for an NFET, a higher threshold voltage device (e.g., an IO transistor device) may have at least one or more than two additional barrier layers, whereas a lower threshold voltage device (e.g., a core logic transistor device) may have few or no additional barrier layers. For a PFET, a higher threshold voltage device (e.g., an IO transistor device) may have few or no additional barrier layers, whereas a lower threshold voltage device (e.g., a core logic transistor device) may have at least one or more than two additional barrier layers. In the immediately preceding discussion, threshold voltage is described in terms of magnitude. As an example, an NFET IO transistor and a PFET IO transistor may have similar threshold voltage in terms of magnitude, but opposite polarity, such as +1 Volt for the NFET IO transistor and −1 Volt for the PFET IO transistor. As such, because each additional barrier layer increases threshold voltage in absolute terms (e.g., +0.1 Volts/layer), such an increase confers an increase to NFET transistor threshold voltage (magnitude) and a decrease to PFET transistor threshold voltage (magnitude).

The gate structure 200 also includes metal fill layer 290. The metal fill layer 290 may include a conductive material such as tungsten, cobalt, ruthenium, iridium, molybdenum, copper, aluminum, or combinations thereof. Between the channels 22A-22C, the metal fill layer 290 is circumferentially surrounded (in the cross-sectional view) by the one or more work function metal layers 900, which are then circumferentially surrounded by the gate dielectric layers 600, which are circumferentially surrounded by the interfacial layer 210. The gate structure 200 may also include a glue layer that is formed between the one or more work function layers 900 and the metal fill layer 290 to increase adhesion. The glue layer is not specifically illustrated in FIG. 12 for simplicity. In some embodiments, a conductive layer is formed over the gate structure 200 and is in contact with the metal fill layer 290, the one or more work function layers 900 and the gate dielectric layers 600. The conductive layer may include fluorine-free tungsten (FFW) or another suitable material. In some embodiments, a dielectric capping layer is present over the conductive layer.

Additional processing may be performed following fabrication of the semiconductor device. For example, gate contacts may be formed that electrically couple to the gate structure 200, and source/drain vias may be formed that electrically couple to the source/drain contacts 120. An interconnect structure (e.g., a “frontside interconnect structure”) may then be formed over the source/drain contacts 120 and the gate contacts. The interconnect structure may include a plurality of interconnect layers, each of which may include one or more dielectric layers with metallic features embedded therein, such as conductive traces and conductive vias, which form electrical connection between devices of the IC chip 10. In some embodiments, a conductive layer or conductive cap is present over the gate structure 200. In some embodiments, dielectric capping layers are present over the gate structure 200 and/or over the source/drain contacts 120. Configurations in which the dielectric capping layers are only present over the gate structure 200 (e.g., no second capping layers are present over the source/drain contacts 120) may be referred to as “single SAC” structures, and configurations in which the capping layers are present over gate structures 200 and source/drain contacts 120 may be referred to as “double SAC” structures.

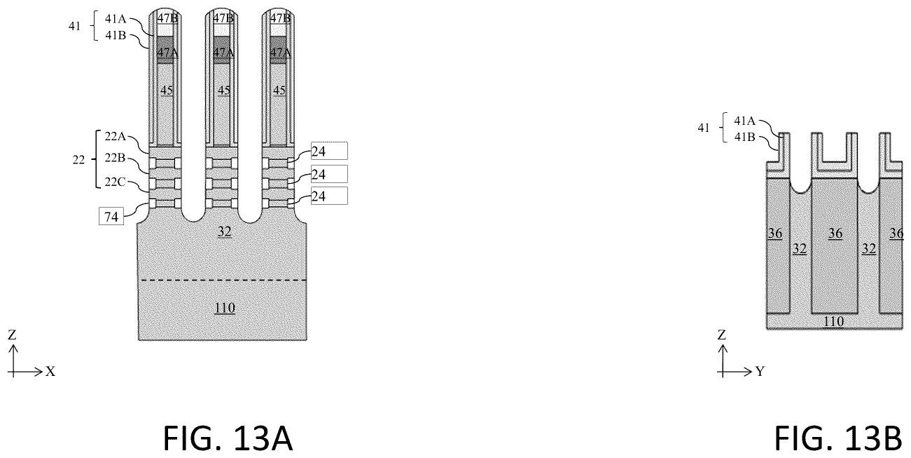

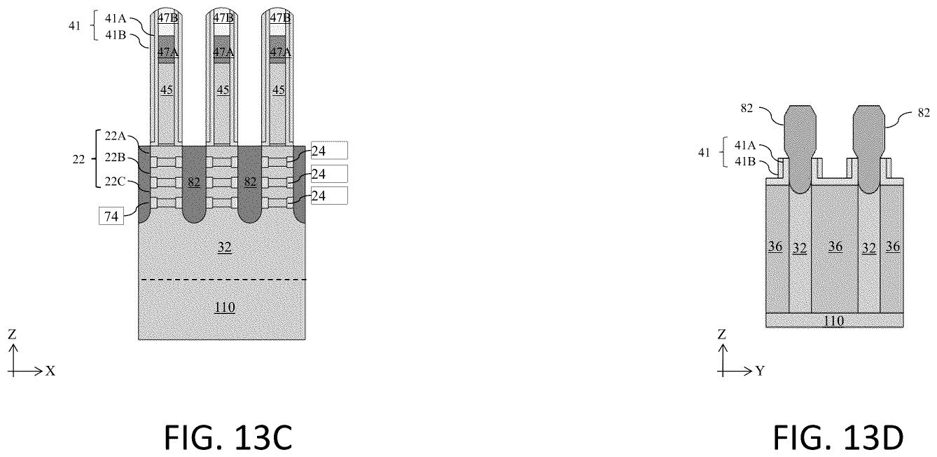

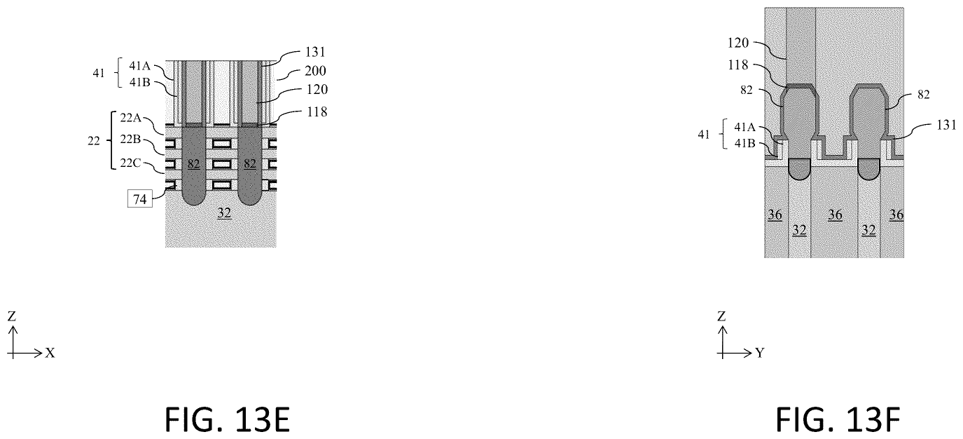

FIGS. 13A-13F are diagrammatic cross-sectional side views illustrating formation of source/drain regions 82 in accordance with various embodiments in which the first and second epitaxial layers 110A, 110B and/or the bottom dielectric layer 800A, 800B are omitted. FIGS. 13A and 13B are substantially the same or similar to FIGS. 7F and 7G.

In FIGS. 13C, 13D, following formation of the source/drain openings 49 and the inner spacers 74, source/drain regions 82 are formed, as shown. The source/drain regions 82 are grown by the same or similar process described with reference to FIGS. 8A-8F. In the embodiment depicted in FIGS. 13A-13F, the source/drain regions 82 grow from the fin 32 and from the channels 22, whereas the source/drain regions 82 in the embodiment depicted in FIGS. 8A-8F may only grow from the channels 22 due to the fins 32 being covered by the first and optionally the second epitaxial layer 110A, 110B and the bottom dielectric layers 800A, 800B.

In FIGS. 13E, 13F, the replacement gates 200 and source/drain contacts 120 are formed, which may be the same as or similar to the description of FIGS. 9A-12 herein.

Embodiments may provide advantages. Protecting the portions of the spacer layer 41 that overlie the isolation regions 36 allows the spacer layer 41 to remain over the isolation regions 36, which protects the isolation regions 36 during formation of source/drain openings 49, the first and second epitaxial layers 110A, 110B, the bottom dielectric layers 800A, 800B and the source/drain regions 82. Inclusion of the first and second epitaxial layers 110A, 110B allows for hybrid Weff based on number of channels that are isolated by the second epitaxial layer 110B. The bottom dielectric layer 800A, 800B prevents mesa leakage current.

In accordance with at least one embodiment, a device includes: a first circuit region including: a first stack of first nanostructures; an isolation region abutting the first stack and positioned between the first stack and another stack of nanostructures that neighbors the first stack; a spacer layer on the isolation region, the spacer layer covering a peripheral portion of an upper surface of the isolation region and a central portion of the upper surface; a first gate structure wrapping around the first nanostructures; a second epitaxial layer abutting one of the first nanostructures; and a first source/drain region that is isolated physically and electrically from the one of the first nanostructures by the second epitaxial layer and is in contact with others of the first nanostructures. The device further includes: a second circuit region offset from the first circuit region, and including: a second stack of second nanostructures having a same number of second nanostructures as that of the first nanostructures of the first stack; a second gate structure wrapping around the second nanostructures; and a second source/drain region that is in contact with a number of the second nanostructures that exceeds a number of the first nanostructures that the first source/drain region is in contact with.

In accordance with at least one embodiment, a device includes: a stack of nanostructures; a gate structure that wraps around the nanostructures; an isolation region between the stack of nanostructures and another stack of nanostructures adjacent thereto along a first direction; a source/drain region that abuts at least one of the nanostructures; and a spacer layer that is on sidewalls of the gate structure and on sidewalls of the source/drain region, the spacer layer covering an area between the source/drain region and a neighboring source/drain region of another transistor along the first direction.

In accordance with at least one embodiment, a method includes: forming a multilayer structure of alternating first semiconductor layers and second semiconductor layers over a substrate; forming a fin and a stack of nanostructures thereover by patterning the multilayer structure; forming an isolation region adjacent the fin; forming a sacrificial gate structure over the stack; forming a spacer layer on sidewalls of the stack and on an upper surface of the isolation region; forming a mask layer on the spacer layer; exposing an upper portion of the stack by recessing the mask layer; forming a source/drain opening with the mask layer covering the isolation region; forming at least one epitaxial layer in the source/drain opening; forming a bottom dielectric layer on the at least one epitaxial layer in the source/drain opening; forming a source/drain region on the bottom dielectric layer; and replacing the sacrificial gate structure with a gate structure that wraps around the nanostructures of the stack.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A device, comprising:
a first circuit region including:
a first stack of first nanostructures;
an isolation region abutting the first stack and positioned between the first stack and another stack of nanostructures that neighbors the first stack;
a spacer layer on the isolation region, the spacer layer covering a peripheral portion of an upper surface of the isolation region and a central portion of the upper surface;
a first gate structure wrapping around the first nanostructures;
a second epitaxial layer abutting one of the first nanostructures; and
a first source/drain region that is isolated physically and electrically from the one of the first nanostructures by the second epitaxial layer and is in contact with others of the first nanostructures; and
a second circuit region offset from the first circuit region, and including:
a second stack of second nanostructures having a same number of second nanostructures as that of the first nanostructures of the first stack;
a second gate structure wrapping around the second nanostructures; and
a second source/drain region that is in contact with a number of the second nanostructures that exceeds a number of the first nanostructures that the first source/drain region is in contact with.

2. The device of claim 1, further comprising:
a first bottom dielectric layer that is positioned between the first source/drain region and the second epitaxial layer; and
a second bottom dielectric layer that is positioned between the second source/drain region and a first epitaxial layer, the second bottom dielectric layer being at a level that is lower than that of the first bottom dielectric layer.

3. The device of claim 1, wherein the spacer layer includes:
a first spacer layer in contact with the isolation region; and
a second spacer layer on the first spacer layer.

4. The device of claim 3, wherein the second spacer layer has an opening that overlaps the isolation region.

5. The device of claim 1, further comprising an interlayer dielectric layer on the isolation region, the interlayer dielectric layer being separated from the isolation region by the spacer layer.

6. The device of claim 1, wherein thickness of the spacer layer on sidewalls of the first source/drain region is less than thickness of the spacer layer on the central portion of the upper surface of the isolation region.

7. A device comprising:
a stack of nanostructures;
a gate structure that wraps around the nanostructures;
an isolation region between the stack of nanostructures and another stack of nanostructures adjacent thereto along a first direction;
a source/drain region that abuts at least one of the nanostructures; and
a spacer layer that is on sidewalls of the gate structure and on sidewalls of the source/drain region, the spacer layer covering an area between the source/drain region and a neighboring source/drain region of another transistor along the first direction.

8. The device of claim 7, wherein the spacer layer entirely covers an upper surface of the isolation region.

9. The device of claim 7, further comprising:
a fin; and
a bottom dielectric layer between the fin and the source/drain region.

10. The device of claim 9, further comprising a source/drain contact that extends through the bottom dielectric layer and contacts the source/drain region.

11. The device of claim 7, further comprising an etch stop layer, the spacer layer being between the etch stop layer and the isolation region.

12. The device of claim 7, wherein thickness of the spacer layer on the sidewalls of the source/drain region is in a range of about 5 nanometers (nm) to about 20 nm and thickness of the spacer layer on the upper surface of the isolation region is in a range of about 2 nm to about 8 nm.

13. The device of claim 7, further comprising an undoped silicon layer that abuts at least another one of the nanostructures, the undoped silicon layer isolating the at least another one from the source/drain region.

14. A method, comprising:
forming a multilayer structure of alternating first semiconductor layers and second semiconductor layers over a substrate;
forming a fin and a stack of nanostructures thereover by patterning the multilayer structure;
forming an isolation region adjacent the fin;
forming a sacrificial gate structure over the stack;
forming a spacer layer on sidewalls of the stack and on an upper surface of the isolation region;
forming a mask layer on the spacer layer;
exposing an upper portion of the stack by recessing the mask layer;
forming a source/drain opening with the mask layer covering the isolation region;
forming at least one epitaxial layer in the source/drain opening;
forming a bottom dielectric layer on the at least one epitaxial layer in the source/drain opening;
forming a source/drain region on the bottom dielectric layer; and
replacing the sacrificial gate structure with a gate structure that wraps around the nanostructures of the stack.

15. The method of claim 14, further comprising removing the mask layer after the forming a source/drain opening and before the forming at least one epitaxial layer.

16. The method of claim 14, wherein the forming at least one epitaxial layer includes:
forming a first epitaxial layer that extends to an upper surface of the fin; and
forming a second epitaxial layer on the first epitaxial layer, the second epitaxial layer extending to a level that is above at least one nanostructure of the stack.

17. The method of claim 16, wherein the second epitaxial layer is formed in a second device region including the stack while a first device region including another stack of nanostructures is masked.

18. The method of claim 17, wherein the forming a bottom dielectric layer includes:
forming a first bottom dielectric layer on the first epitaxial layer in the second device region; and
forming a second bottom dielectric layer on the second epitaxial layer in the first device region, the second bottom dielectric layer being at a level above that of the first bottom dielectric layer.

19. The method of claim 14, wherein the forming a spacer layer includes forming the spacer layer to a first thickness, and wherein the spacer layer has a second thickness that is less than the first thickness before the forming a source/drain region.

20. The method of claim 19, wherein:
the forming a spacer layer includes:
forming a first spacer layer that covers the upper surface of the isolation region; and
forming a second spacer layer on the first spacer layer; and
at least one opening is present in the second spacer layer over the isolation region when the source/drain region is formed.
